(19) United States
(12) Patent Application Publication
(10) Pub. No.: US 2026/0314376 A1
(43) Pub. Date: Oct. 8, 2026

(54) INTEGRATED CIRCUIT DEVICE AND METHOD

(71) Applicant: TAIWAN SEMICONDUCTOR MANUFACTURING COMPANY, LTD., Hsinchu (TW)

(72) Inventors: Wei-Cheng KANG, Hsinchu (TW); Jun-YU LIN, Hsinchu (TW); Meng-Hung SHEN, Hsinchu (TW); Shih-Wei PENG, Hsinchu (TW); Wei-Cheng LIN, Hsinchu (TW); Jiann-Tyng TZENG, Hsinchu (TW)

(21) Appl. No.: 19/298,930

(22) Filed: Aug. 13, 2025

Related U.S. Application Data
(60) Provisional application No. 63/783,049, filed on Apr. 3, 2025.

(51) Int. Cl. H01L 23/528; H01L 23/522; H10D 89/10

(52) U.S. Cl. CPC H10W 20/427; H10D 89/10; H10W 20/42; H10W 20/43; H10W 20/435

(57) ABSTRACT

An IC device includes three power rails, the second power rail aligned with a line midway between the first and third power rails, and first and second adjacent rows of cells extending between the first and third power rails. Each cell includes two active areas extending between isolation structures, first and second cells of the first row are aligned with third and fourth cells of the second row, a first active area of the first cell has a first width and a first distance from the center line, first active areas of the second and fourth cells have a second width greater than the first width and a second distance from the center line less than the first distance, and a first active area of the third cell has a third width greater than the second width and a third distance from the center line less than the second distance.

### PRIORITY CLAIM

The present application claims the priority of U.S. Provisional Application No. 63/783,049, filed Apr. 3, 2025, which is incorporated herein by reference in its entirety.

### BACKGROUND

The ongoing trend in miniaturizing integrated circuits (ICs) has resulted in progressively smaller devices which consume less power, yet provide more functionality at higher speeds than earlier technologies. Miniaturization has been achieved through design and manufacturing innovations tied to increasingly strict specifications. Various electronic design automation (EDA) tools are used to generate, revise, and verify designs for semiconductor devices while ensuring that design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a plan view of an IC device and layout diagram, in accordance with some embodiments.

FIG. 2 is a plan view of an IC device and layout diagram, in accordance with some embodiments.

FIG. 3 is a plan view of an IC device and layout diagram, in accordance with some embodiments.

FIGS. 4A and 4B are plan and cross-sectional views of an IC device and layout diagram, in accordance with some embodiments.

FIG. 5 is a plan view of an IC device and layout diagram, in accordance with some embodiments.

FIG. 6 is a plan view of an IC device and layout diagram, in accordance with some embodiments.

FIG. 7 is a flowchart of a method of manufacturing an IC device, in accordance with some embodiments.

FIGS. 8A-8C are flowcharts of a method of manufacturing an IC device based on an IC layout diagram, in accordance with some embodiments.

FIG. 9 is a block diagram of an IC design system, in accordance with some embodiments.

FIG. 10 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an integrated circuit (IC) device, layout diagram method, system, and manufacturing method are directed to functional cells having a uniform height in which a first cell in a first row of cells aligned with a second cell in an adjacent second row of cells includes an active area wider than an active area of the second cell and further from a center line of the two rows than the active area of the second cell. The active area of the first cell is also wider than and closer to the center line than active areas of other cells of the first row, and the active area of the second cell is also narrower and further from the center line than active areas of other cells of the second row. In some embodiments, the first and second rows of cells are arranged accordingly based on the active area of the first cell being identified as a critical path.

Corresponding IC devices are thereby capable of including functional cells arranged according to a single pitch and including the relatively wide active area cells placed conditioned on including critical paths, thereby improving circuit area efficiency compared to other approaches, e.g., those in which both critical and non-critical path cells are included in rows of cells having cell heights corresponding to wide active areas and thereby greater than cell heights of other rows including only non-critical path cells including narrow active areas.

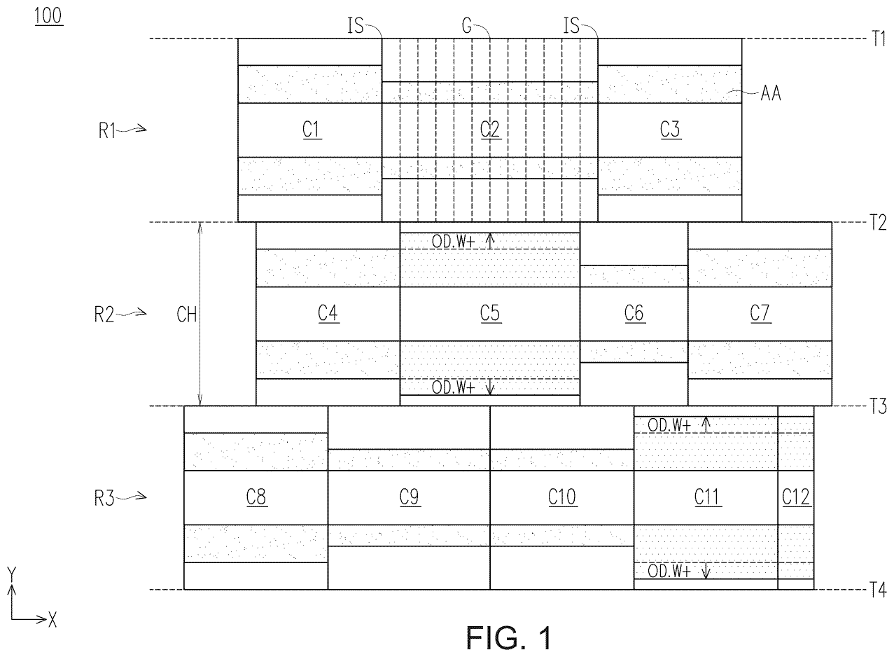

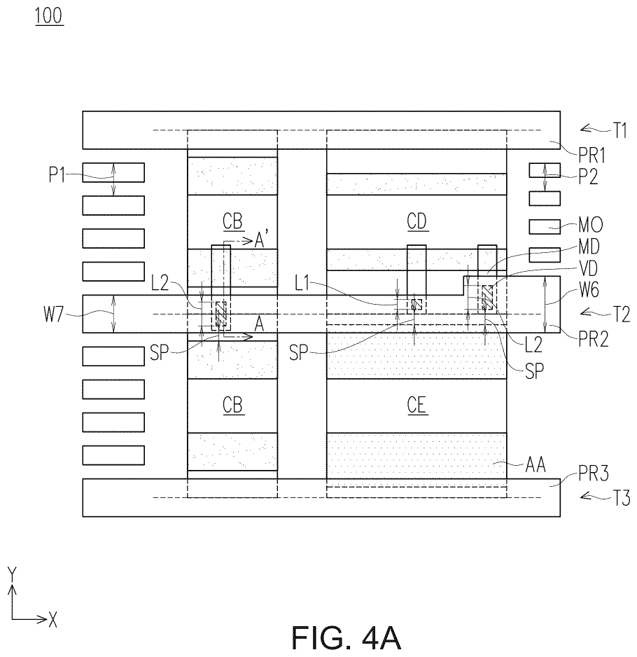

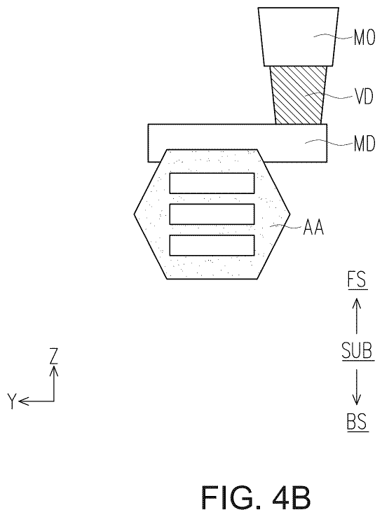

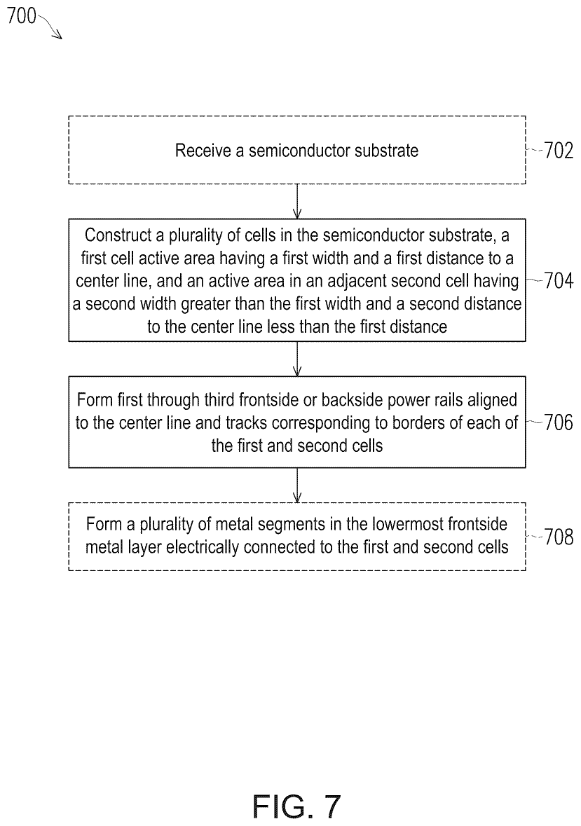

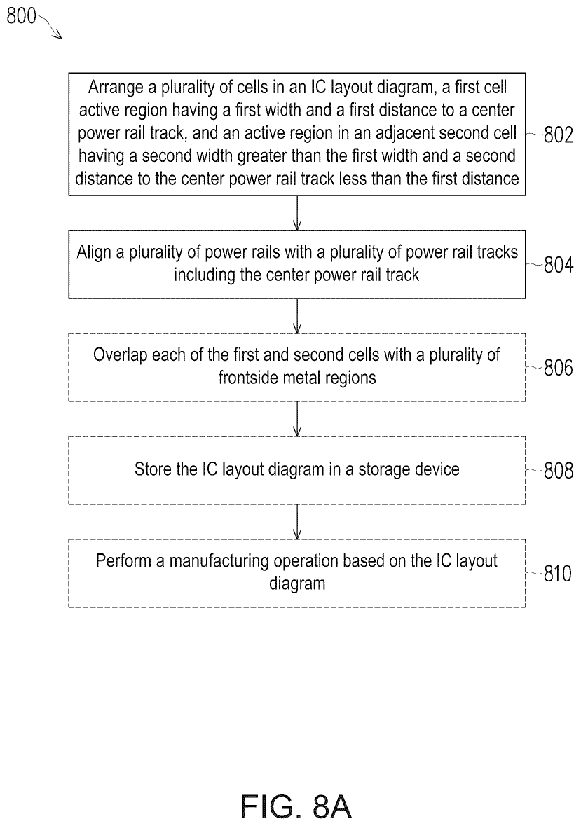

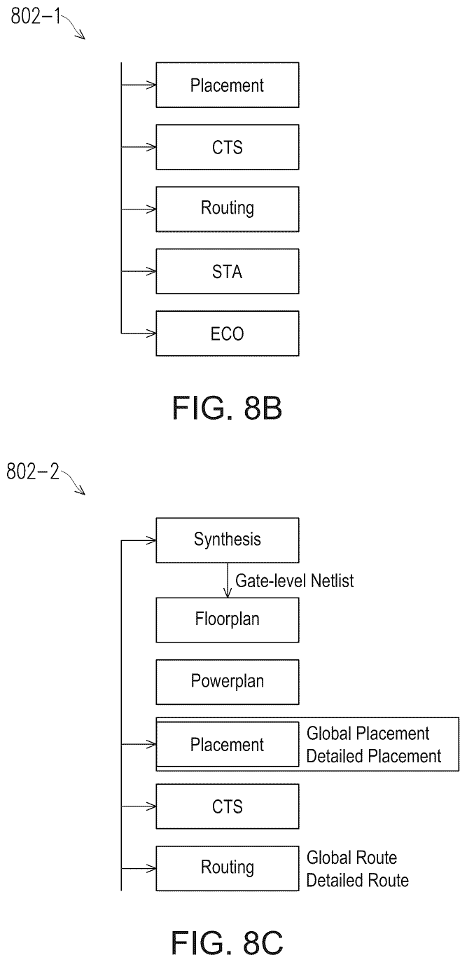

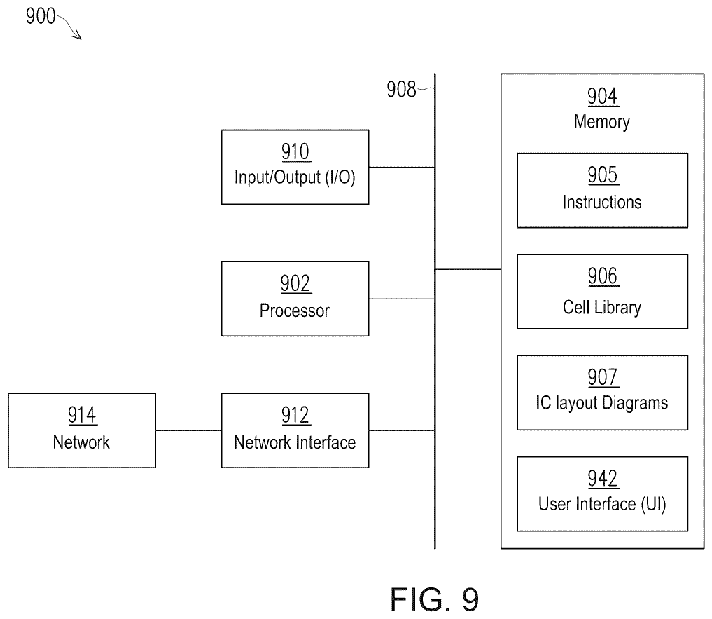

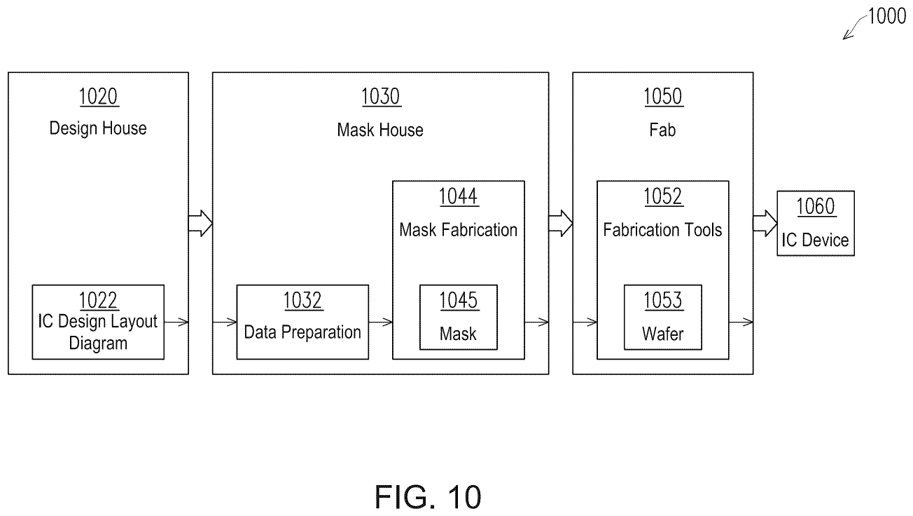

In accordance with various embodiments, each of FIGS. 1-4A, 5, and 6 is a plan view, and FIG. 4B is a cross-sectional view, of an IC device 100 and corresponding IC layout diagram 100, FIG. 7 is a flowchart of a method 700 of manufacturing an IC device, FIGS. 8A-8C are flowcharts of a method 800 of manufacturing an IC device based on an IC layout diagram, e.g., using IC design system 900 depicted in FIG. 9 and/or in accordance with an IC manufacturing flow 1000 depicted FIG. 10.

Each of the figures herein, e.g., FIGS. 1-6, is simplified for the purpose of illustration. The figures are views of IC structures, devices, and layout diagrams with various features included and excluded to facilitate the discussion below. In various embodiments, an IC structure, device and/or layout diagram includes one or more features corresponding to power distribution structures, metal interconnects, contacts, vias, gate structures, source/drain (S/D) structures, active areas, bulk connections, or other transistor elements, isolation structures, or the like, in addition to the features depicted in FIGS. 1-6.

In each embodiment of IC layout diagram/device 100, reference designators represent both IC device features and the IC layout features used to at least partially define the corresponding IC device features in a manufacturing process, e.g., method 700 discussed below with respect to FIG. 7 and/or the IC manufacturing flow associated with IC manufacturing system 1000 discussed below with respect to FIG. 10. Accordingly, each embodiment of IC layout diagram/device 100 represents a view of both an embodiment of IC layout diagram 100 and a corresponding embodiment of IC device 100.

In FIGS. 1-6, for the purpose of clarity, all instances of each feature included in the corresponding instance of IC layout diagram/device 100 are not necessarily labeled. Unless otherwise indicated, the numbers of instances of the various features depicted in FIGS. 1-6, e.g., numbers of rows, tracks, or cells in a given row, are non-limiting examples provided for the purpose of illustration. Embodiments of IC layout diagram/device 100 including numbers of instances of features other than those depicted in FIGS. 1-6 are within the scope of the present disclosure.

Each embodiment of IC layout diagram/device 100 discussed below includes arrangements of some or all of a substrate, an active region/area, a metal-diffusion (MD) region/segment, a contact and/or interconnect region/structure, a gate region/structure, a metal region/segment, a via region/structure, and/or a dielectric region/layer, each discussed below.

A substrate, e.g., a substrate SUB, is a portion, e.g., a die, or all of a semiconductor or other wafer, e.g., a silicon (Si) wafer, or an epitaxial Si layer, suitable for forming one or more IC devices, e.g., IC device 100. In each of the embodiments discussed below, a substrate, e.g., a semiconductor substrate, includes a front side, e.g., a front side FS, within which a first subset of the features of the IC devices are formed through a first set of manufacturing processes, e.g., front-end-of-line (FEOL) processes, middle-end-of-line (MEOL) processes, and back-end-of-line (BEOL) processes, and a back side, e.g., a back side BS, within which a second subset of the features of the IC devices are formed through a second set of manufacturing processes, e.g., backside metallization processes, performed after the first set of manufacturing processes are performed.

An active region/area, e.g., an active region/area AA, is a region in an IC layout diagram included in a manufacturing process as part of defining an active area, also referred to as an oxide diffusion or definition (OD) in some embodiments, in the substrate, either directly or in an n-well or p-well region/area, in which one or more IC device features are formed.

In various embodiments, an active area (structure) includes one or more of a semiconductor material, e.g., silicon (Si), silicon-germanium (SiGe), silicon-carbide (SiC), or the like, a dopant material, e.g., boron (B), aluminum (Al), phosphorous (P), arsenic (As), gallium (Ga), or another suitable material.

In some embodiments, an active region is a region in an IC layout diagram included in the manufacturing process as part of defining a nano-sheet structure, e.g., a continuous volume of one or more layers of one or more semiconductor materials having either n-type or p-type doping. In various embodiments, individual nano-sheet layers include a single monolayer or multiple monolayers of a given semiconductor material.

An MD region/segment, e.g., MD region/segment MD, is a conductive region in the IC layout diagram included in the manufacturing process as part of defining a contact or interconnect structure, also referred to as a conductive segment, line, trace, or structure, in and/or on an active area and/or the substrate. In some embodiments, an MD region overlaps an active area at a location of one or more source/drain (S/D) regions in the IC layout diagram. In some embodiments, an MD segment contacts and is electrically connected to one or more S/D volumes or structures of the active area and/or is considered to correspond to an S/D structure.

In some embodiments, an MD segment includes a portion of at least one metal layer, e.g., an MD or contact layer, overlying and contacting the active area and/or substrate and having a thickness sufficiently small to enable formation of an insulation layer between the MD segment and an overlying metal layer, e.g., a first frontside metal layer. In various embodiments, an MD segment includes one or more of copper (Cu), silver (Ag), tungsten (W), titanium (Ti), nickel (Ni), tin (Sn), aluminum (Al) or another metal or material suitable for providing a low resistance electrical connection between IC structure elements, i.e., a resistance level below a predetermined threshold corresponding to one or more tolerance levels of a resistance-based effect on circuit performance.

In various embodiments, an MD segment includes a section of a substrate and/or an epitaxial layer having a doping level, e.g., based on an implantation process, sufficient to cause the structure to have the low resistance level. In various embodiments, a doped contact or interconnect structure includes one or more dopant materials having doping concentrations of about 1*1016 per cubic centimeter (cm⁻³) or greater.

In some embodiments, a manufacturing process includes two or more MD segment layers, and an MD region/segment refers to one or more of the two or more MD segment layers in the manufacturing process.

A gate region/structure, e.g., a gate region/structure G, also referred to as a gate G in some embodiments, is a region in the IC layout diagram included in the manufacturing process as part of defining a gate structure. A gate structure is a volume including one or more conductive segments, e.g., a gate electrode, including one or more conductive materials, e.g., polysilicon, copper (Cu), aluminum (Al), tungsten (W), cobalt (Co), ruthenium (Ru), or one or more other metals or other suitable materials, substantially surrounded by one or more insulating materials, the one or more conductive segments thereby being configured to control a voltage provided at an adjacent gate dielectric layer.

A gate dielectric layer, e.g., a gate dielectric layer of a gate structure G, is a volume including one or more insulating materials, e.g., silicon dioxide, silicon nitride (Si₃N₄), and/or one or more other suitable material such as a low-k material having a k value less than 3.8 or a high-k material having a k value greater than 3.8 or 7.0 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

In some embodiments, a gate region/structure corresponds to a dummy gate region/structure, e.g., a dummy gate region/structure IS. In some embodiments, a dummy gate region/structure includes a gate electrode electrically connected, e.g., tied-off, to one or more features, e.g., a power rail or other metal segment or an adjacent instance of a S/D region/structure such that a transistor corresponding to the dummy gate region/structure and overlapping/underlying active region/area is switched off by design.

In some embodiments, a dummy gate region/structure corresponds to an isolation feature/structure including one or more regions in the IC layout diagram included in the manufacturing process as part of defining an isolation structure configured to electrically isolate adjacent features from each other. In some embodiments, an isolation feature/structure includes a dielectric region/volume positioned between the adjacent features, e.g., instances of active region/area AA. A dielectric region is a region in the IC layout diagram included in the manufacturing process as part of defining a volume including one or more insulating materials.

A metal line or region, e.g., a frontside metal region/segment M0, is a region in the IC layout diagram included in the manufacturing process as part of defining a metal line, or segment, including one or more conductive materials, e.g., polysilicon, copper (Cu), aluminum (Al), tungsten (W), cobalt (Co), ruthenium (Ru), or one or more other metals or other suitable materials, in a given frontside or backside metal layer of the manufacturing process.

In some embodiments, a metal region/segment, e.g., metal region/segment M0, corresponds to a first, or lowermost, frontside metal layer (also referred to as a metal zero layer or frontside metal zero layer in some embodiments), or a second or higher level frontside metal layer of the manufacturing process. In some embodiments, a second frontside metal layer is referred to as a metal one layer or frontside metal one layer and a second frontside metal region/segment is referred to as a metal one region/segment.

In some embodiments, a backside metal region/segment corresponds to a first, or lowermost, backside metal layer (also referred to as a backside metal zero layer in some embodiments), or a second or higher level backside metal layer of the manufacturing process.

In some embodiments, a frontside or backside metal region/segment, e.g., a power rail PR1-PR3, corresponds to a component of a power distribution network configured to distribute one or both of a power supply voltage, e.g., a power supply voltage VDD, and/or a reference or ground voltage, e.g., a reference voltage VSS. The power distribution network component is electrically connected to one or more features, e.g., additional metal regions/segments and/or via regions/structures, configured to distribute the corresponding power supply or reference voltage and be electrically isolated from IC components outside the distribution network.

A via region/structure, e.g., a via region/structure VD, also referred to as a via or interconnect in some embodiments, is a region in the IC layout diagram included in the manufacturing process as part of defining a via/interconnect structure including one or more conductive materials configured to provide an electrical connection between a first, e.g., overlying, conductive structure, e.g., a frontside metal segment M0, and a second, e.g., underlying, conductive structure, e.g., an MD segment MD, aligned with the first conductive structure in a Z direction.

FIG. 1 depicts a plan view of IC layout diagram/device 100 and X and Y directions, in accordance with some embodiments. In the embodiment depicted in FIG. 1, IC layout diagram/device 100 includes adjacent rows R1-R3 of cells aligned along tracks T1-T4. Row R1 includes cells C1-C3, row R2 includes cells C4-C7, and row R3 includes cells C8-C12.

Tracks, e.g., tracks T1-T4, are lines in IC layout diagram 100 included in the manufacturing process as part of defining locations of features in IC device 100 that correspond to regions aligned to the tracks in IC layout diagram 100. In some embodiments, the tracks correspond to power rails, e.g., power rails PR1-PR3 discussed below, aligned to the tracks in IC layout diagram 100 and spaced apart in the Y direction accordingly in IC device 100. In some embodiments, the tracks correspond to one or both of frontside power rails or backside power rails. In some embodiments, the tracks correspond to frontside and/or backside metal regions/segments other than power rails, e.g., signal lines.

In the embodiment depicted in FIG. 1, tracks T1-T4 correspond to a first frontside metal layer. Embodiments in which tracks T1-T4 correspond to one or more frontside metal layers above the first metal layer and/or to one or more backside metal layers are within the scope of the present disclosure.

Tracks T1-T4 have a pitch corresponding to a cell height CH in the Y direction. In some embodiments, the pitch is referred to as pitch CH, track pitch CH, or power rail pitch CH. In some embodiments, tracks T1-T4 are referred to as power rail tracks T1-T4.

A cell, e.g., a cell C1-C12, is a predefined portion of IC layout diagram 100 included in the manufacturing process as part of defining a functional device within IC device 100. Cells are configured to provide common, low-level functions, often performed by transistors based on gate regions, e.g., gate regions G, that intersect active regions, e.g., active regions AA. The elements of a cell are arranged within a cell boundary and electrically connected to other cells through interconnect structures, e.g., instances of metal regions/segments and via regions/structures.

In some embodiments, a cell is stored as one or more files, e.g., database files, in a storage device, e.g., a cell library such as a cell library 906 discussed below with respect to FIG. 9, and IC layout diagram 100 is stored as one or more files, e.g., database files, in a separate or the same storage device, e.g., as IC layout diagrams 907 discussed below with respect to FIG. 9.

In various embodiments, a cell is one or more of a standard cell, a custom cell, an engineering change order (ECO) cell, a logic cell, a memory cell, or another type of functional cell capable of being defined in an IC layout diagram. In various embodiments, a cell includes one or more of a transmission gate, an inverter, an AND, OR, NAND, NOR, XOR, AND-OR-Invert (AOI), or OR-AND-Invert (OAI) gate, a multiplexer, a flip-flop, a buffer, a latch, a delay element, or a clock device.

In the embodiment depicted in FIG. 1, as illustrated by cell C2, a cell boundary (not labeled) includes two instances of dummy gate region/structure IS extending in the Y direction from a first one of tracks T1-T4 to a second one of tracks T1-T4 and the portions of the first and second ones of tracks T1-T4 extending in the X direction between the instances of dummy gate region/structure IS.

A length of each instance of dummy gate region/structure IS is equal to cell height CH, and cells C1-C12 of rows R1-R3 have a uniform value of cell height CH.

A cell includes instances of gate region/structure G extending in the Y direction between the instances of dummy gate region/structure IS from the first one of tracks T1-T4 to the second one of tracks T1-T4. The cell also includes a total of two instances of active region/area AA extending in the X direction between the instances of dummy gate region/structure IS, and the instances of gate region/structure G overlap/overlie each instance of active region/area AA at locations corresponding to transistors of the cell.

The instances of gate region/structure G and dummy gate region/structure IS are spaced apart along the X direction in accordance with a gate pitch, also referred to as a poly pitch or contacted poly pitch (CPP) in some embodiments. A width of a given cell in the X direction thereby corresponds to the gate pitch and the number of instances of gate region/structure G between the two instances of dummy gate region/structure IS.

The instances of gate region/structure G and dummy gate region/structure IS in a given row are aligned with the instances of gate region/structure G and dummy gate region/structure IS in each other row such that a given instance of gate region/structure G or dummy gate region/structure IS in one row is aligned with at least one instance of gate region/structure G or dummy gate region/structure IS in an adjacent row.

In some embodiments, some or all of the instances of gate region/structure G of a cell include discontinuities, e.g., corresponding to cut-gate regions in IC layout diagram 100, at the locations corresponding to the first one of tracks T1-T4 and/or the second one of tracks T1-T4. In some embodiments, the instances of gate region/structure G of a cell include discontinuities at one or more other locations, e.g., between the two instances of active region/area AA.

In some embodiments, the first instance of active region/area AA in a cell is one of an n-type or a p-type active region/area, and the second instance of active region/area AA in the cell is the other of the n-type or the p-type active region/area.

In some embodiments, a given one of tracks T1-T4 corresponds to a power supply voltage power rail, and the instances of active region/area AA closest to the given one of tracks T1-T4 are the p-type active region/area. In some embodiments, a given one of tracks T1-T4 corresponds to a reference voltage, e.g., ground, power rail, and the instances of active region/area AA closest to the given one of tracks T1-T4 are the n-type active region/area. In some embodiments, tracks corresponding to power supply voltage power rails alternate with tracks corresponding to reference voltage power rails.

As further discussed below, an instance of active region/area AA in a given cell has a width in the Y direction (not labeled in FIG. 1) capable of being the same or different from one or more widths of other instances of active region/area AA in the given cell or in another cell of IC layout diagram/device 100. In some embodiments, an instance of active region/area AA in a given cell has a uniform width across an entirety of the width of the cell.

As the width of an instance of active region/area AA increases, a current driving capability, also referred to as drivability or current drivability in some embodiments, of the one or more transistors corresponding to the instance of active region/area AA also increases.

In the embodiment depicted in FIG. 1, each of cells C5, C11, and C12 includes each of the two instances of active region/area AA having a width greater than the widths of the instances of active region/area AA in cells C1-C4 and C6-C10. The corresponding width increase OD.W+ is further discussed below.

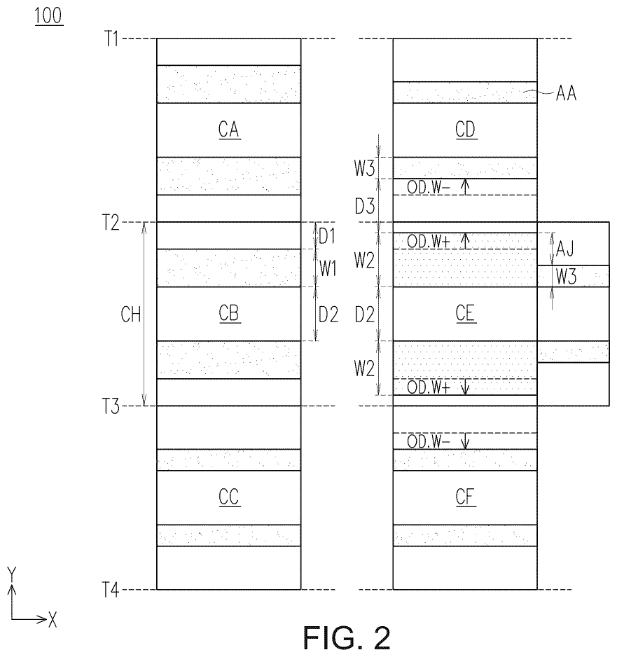

FIG. 2 depicts a plan view of IC layout diagram/device 100 and the X and Y directions, in accordance with some embodiments. In the embodiment depicted in FIG. 2, IC layout diagram/device 100 includes adjacent cells CA-CC and adjacent cells CD-CF. Cells CA-CD and CF correspond to cells C1-C4 and C6-C10, and cell CE corresponds to cells C5, C11, and C12 discussed above with respect to FIG. 1.

The cell alignments in the Y direction depicted in FIGS. 2-6, e.g., including aligned borders, are simplified for the purpose of illustration. In various embodiments, cells are considered to be adjacent based on portions of one or both of two cells being aligned in the Y direction, e.g., as discussed above with respect to FIG. 1.

Cell CB includes a first instance of active region/area AA having a width W1, a distance D1 from track T2, and a distance D2 from a second instance of active region/area AA. Based on pitch/cell height CH, track T2 is midway between tracks T1 and T3 and is referred to as center line T2 in some embodiments.

In some embodiments, distance D1 is equal to or greater than a spacing rule for a minimum distance between an active area and a cell border for a process used to manufacture IC device 100 based on IC layout diagram 100. In some embodiments, distance D2 is equal to or greater than a spacing rule for a minimum distance between active area instances for the process. In some embodiments, distance D2 is equal to or greater than a spacing rule for a minimum distance between an n-type active area and a p-type active area for the process. In some embodiments, distance D2 is equal to twice distance D1.

Cell CE includes a first instance of active region/area AA having a width W2 and a distance D3 from a first instance of active region/area AA in adjacent cell CD. Width W2 is greater than width W1 by a value of width increase OD.W+.

In some embodiments, distance D3 is equal to or greater than a spacing rule for a minimum distance between active area instances for the process. In some embodiments, distance D3 is equal to or greater than a spacing rule for a minimum distance between instances of a same one of an n-type active area or a p-type active area for the process. In some embodiments, distance D3 is equal to distance D2.

The first instance of active region/area AA in cell CD has a width W3 less than width W1 by a value of a width decrease OD.W−. In some embodiments, the value of width increase OD.W+ is equal to the value of width decrease OD.W−. In some embodiments, e.g., those in which the value of width increase OD.W+ is equal to the value of width decrease OD.W−, a distance (not labeled) between the instances of active region/area AA in cells CA and CB closest to track T2 is also equal to distance D3.

A distance (not labeled) between the first instance of active region/area AA in cell CE and track T2 is thereby equal to distance D1 minus the value of width increase OD.W+, a distance (not labeled) between the first instance of active region/area AA in cell CD and track T2 is thereby equal to distance D1 plus the value of width decrease OD.W−, and a sum of the distances between track T2 and the first instances of active region/area AA in cells CD and CE is equal to distance D3.

At a border of cell CE, the first instance of active region/area AA includes an edge AJ, also referred to as an active area jog AJ in some embodiments, extending in the Y direction a distance equal to a difference between width W2 and width W3 of an adjacent instance of active region/area AA. In some embodiments, the adjacent instance of active region/area AA has a width less than width W2 other than width W3.

Based on the combination of the first instance of active region/area AA in cell CE having width W2, the first instance of active region/area AA in cell CD having width W3, and the two instances of active region/area AA being separated by distance D3, cell CE has cell height CH and includes the first instance of active region/area AA having a greater current driving capability than the capabilities of instances of active region/area AA in other cells having cell height CH, e.g., cell CB.

IC device 100 based on IC layout diagram 100 is thereby capable of including cells arranged according to cell height CH and including the relatively wide active area cells placed conditioned on including critical paths, thereby improving circuit area efficiency compared to other approaches, e.g., those in which both critical and non-critical path cells are included in rows of cells having cell heights corresponding to wide active areas and thereby greater than cell heights of other rows including only non-critical path cells including narrow active areas.

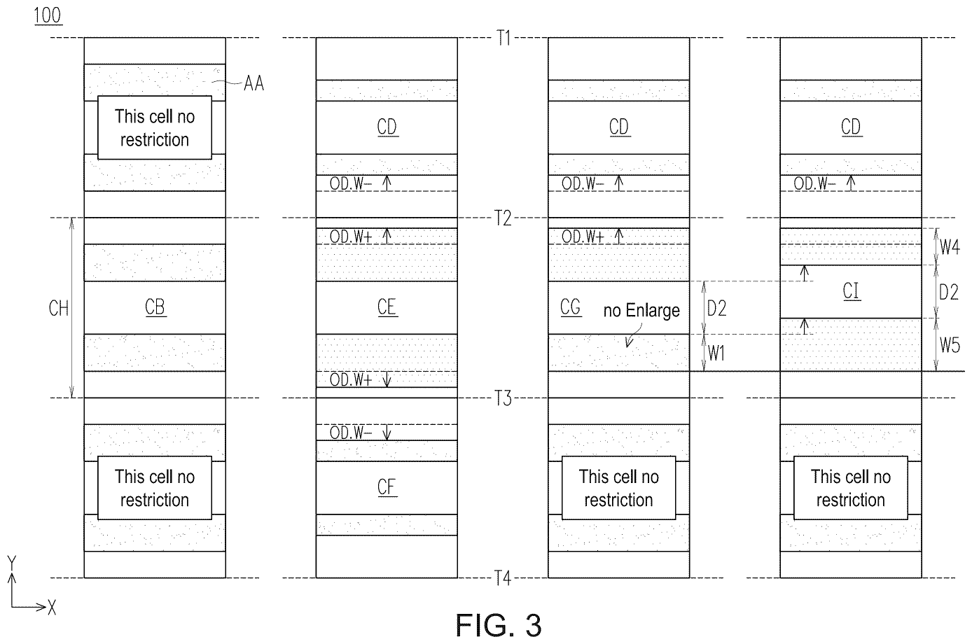

FIG. 3 depicts a plan view of IC layout diagram/device 100 and the X and Y directions, in accordance with some embodiments. In the embodiment depicted in FIG. 3, IC layout diagram/device 100 includes adjacent instances of cell CB (two instances not labeled and indicating no restriction) corresponding to cells CA-CC discussed above with respect to FIG. 2, adjacent cells CD-CF discussed above with respect to FIG. 2, adjacent cells CD, CG, and CB, and adjacent cells CD, CI, and CB.

As depicted in each of FIGS. 2 and 3, cell CE includes each of the two instances of active region/area AA separated from each other by distance D2 and having width W2 based on width increase OD.W+ and being adjacent to instances of active region/area AA in cells CD and CF having width W3 based on width decrease OD.W−.

Cell CG includes a first instance of active region/area AA having width W2 based on width increase OD.W+ and being adjacent to the instance of active region/area AA in cell CD having width W3 based on width decrease OD.W− and a second instance of active region/area AA separated from the first instance of active region/area AA by distance D2, having width W1 and adjacent to an instance of active region/area AA in cell CB having width W1.

Compared to cell CE, based on the second instance of active region/area AA having no width increase, cell CG is capable of being placed adjacent to a cell with no restriction with a tradeoff of including only a single instance of active region/area AA having an increased current driving capability instead of both instances of active region/area AA having an increased current driving capability.

Cell CI includes each of the two instances of active region/area AA separated from each other by distance D2 and having respective widths W4 and W5 based on an aggregate width increase (exclusively in the positive Y direction) equal to width increase OD.W+. In some embodiments, width W4 is equal to width W5 based on each of the two instances of active region/area AA having a width increase equal to half of width increase OD.W+.

The instance of active region/area AA having width W4 is adjacent to the instance of active region/area AA in cell CD having width W3 based on width decrease OD.W− and the instance of active region/area AA having width W5 is adjacent to an instance of active region/area AA in cell CB having width W1.

Compared to cell CE, based on the second instance of active region/area AA having no width increase in the negative Y direction, cell CI is capable of being placed adjacent to a cell with no restriction with a tradeoff of including the instances of active region/area AA having less of an increased current driving capability than that of the two instances of active region/area AA in cell CE.

The alignments, uniform widths, and numbers of adjacent cells depicted in FIGS. 2 and 3 are non-limiting examples provided for the purpose of illustration. Embodiments of IC layout diagram/device 100 including other arrangements of adjacent cells, e.g., as depicted in FIG. 1, are within the scope of the present disclosure.

FIG. 4A depicts a plan view of IC layout diagram/device 100 and the X and Y directions and FIG. 4B depicts a cross-sectional view of IC layout diagram/device 100 and the Y and Z directions, in accordance with some embodiments. The cross-sectional view of FIG. 4B corresponds to a Y-Z plane that intersects the X-Y plane of the plan view of FIG. 4A along a line A-A′.

The cross-sectional arrangement corresponding to line A-A′ depicted in FIG. 4B is a non-limiting example provided for the purpose of illustration. In various embodiments, embodiments of IC layout diagram/device 100 include the features depicted in FIG. 4B having other cross-sectional arrangements, e.g., having opposite orientations, varying alignments, and/or including multiple instances of the various features.

In the embodiment depicted in FIG. 4A, IC layout diagram/device 100 includes adjacent instances of cell CB, adjacent instances of cells CD and CE, and frontside power rails PR1-PR3 aligned with respective tracks T1-T3.

As depicted in FIGS. 4A and 4B, IC layout diagram/device 100 also includes instances of MD region/segment MD overlapping/overlying (in the positive Z direction) instances of active region/area AA, instances of via region/structure VD overlapping/overlying the instances of MD region/segment MD, and instances of frontside metal region/segment M0 (including power rails PR1-PR3) overlapping/overlying the instances of via region/structure VD.

Power rail PR2 overlaps/overlies the corresponding instances of via region/structure VD and MD region/segment MD between the instances of active region/area AA closest to track T2. In the case of adjacent cells CB, the instance of via region/structure VD and the instance of MD region/segment MD each intersect track T2, and the instance of MD region/segment MD is separated from the adjacent instance of active region/area AA by a distance SP.

In some embodiments, distance SP is greater than or equal to a spacing rule for a minimum distance between an active area and an MD segment for a process used to manufacture IC device 100 based on IC layout diagram 100.

In the case of adjacent cells CD and CE, FIG. 4A illustrates two options for maintaining distance SP between the instance of MD region/segment MD and the adjacent instance of active region/area AA, each of which includes the instance of MD region/segment MD having an endpoint further in the positive Y direction than an endpoint of the corresponding instance of MD region/segment MD in the case of adjacent cells CB.

In the first option, the instance of via region/structure VD has a length L1 in the Y direction less than a length L2 of the instance of via region/structure VD in the case of adjacent cells CB. The relatively smaller length L1 of the instance of via region/structure VD results in a relatively higher via resistance but allows the instances of frontside metal region/segment M0 to have a same pitch P1 as in the case of adjacent cells CB.

In the second option, the instance of via region/structure VD has length L2 in the Y direction equal to length L2 of the instance of via region/structure VD in the case of adjacent cells CB and the instance of power rail PR2 has a width W6 in the Y direction greater than a width W7 of the instance of power rail PR2 in the case of adjacent cells CB. In various embodiments, the instance of power rail PR2 has the increased width W6 across an entirety of at least one of cells CD or CE or across one or more portions of one or both of cells CD and CE.

The equal lengths of the instances of via region/structure VD result in an equal via resistance but requires the instances of frontside metal region/segment M0 to have a pitch P2 less than pitch P1, and accordingly smaller widths and higher resistance values, than in the case of adjacent cells CB.

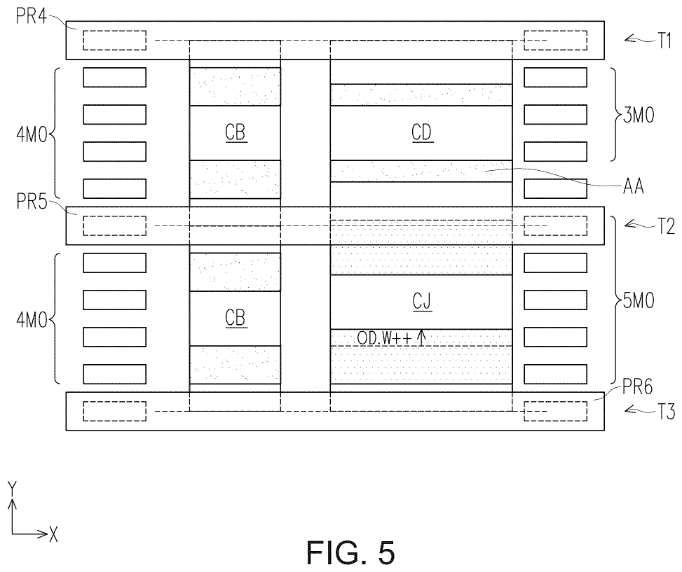

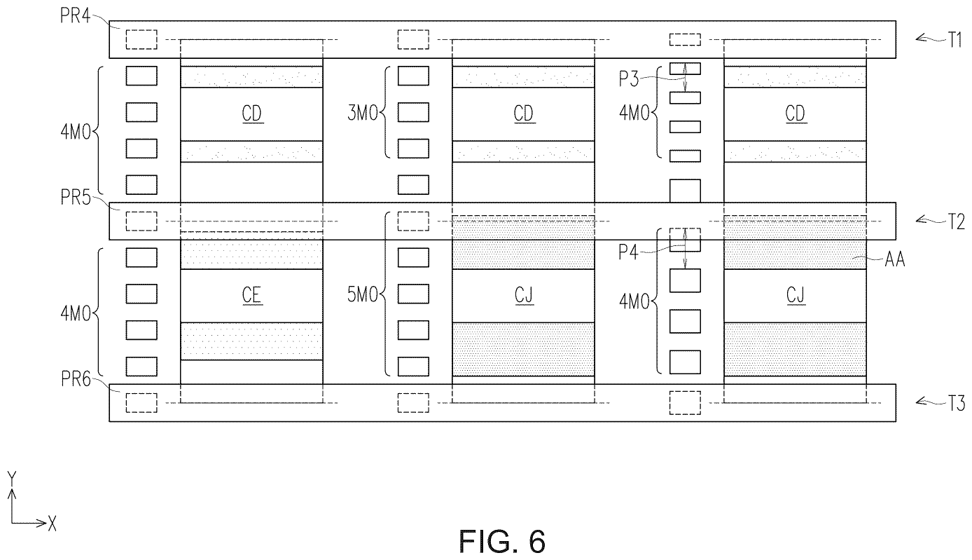

FIGS. 5 and 6 depict plan views of IC layout diagram/device 100 and the X and Y directions, in accordance with some embodiments. In the embodiments depicted in FIGS. 5 and 6, IC layout diagram/device 100 includes adjacent instances of cell CB, adjacent instances of cell CD and a cell CJ, backside power rails PR4-PR6 aligned with respective tracks T1-T3, and instances of frontside metal region/segment M0 including, in some embodiments, instances of frontside metal region/segment M0 aligned with tracks T1-T3.

Cell CJ is similar to cell CI discussed above except that one or both of the two instances of active region/area AA has a width (not labeled) based on a width increase OD.W++ greater than width increase OD.W+ such that the first instance of active region/area AA extends in the positive Y direction to or beyond track T2. Accordingly, the distance between the first instance of active region/area AA in cell CJ and track T2 is equal to zero or is considered to be less than zero, e.g., to have a negative value.

In the embodiment depicted in FIG. 5, IC layout diagram/device 100 includes a total of four locations, e.g., tracks, corresponding to instances of frontside metal region/segment M0 aligned with each of the adjacent instances of cell CB, in addition to the locations corresponding to tracks T1-T3. In the case of the adjacent instances of cells CD and CJ, a total of three locations corresponding to instances of frontside metal region/segment M0 are aligned with cell CD, a fourth location corresponds to a frontside border between cells CD and CJ, and track T2 and four locations, a total of five locations, corresponding to instances of frontside metal region/segment M0 are aligned with cell CJ.

In the embodiment depicted in FIG. 6, IC layout diagram/device 100 includes the total of four locations corresponding to instances of frontside metal region/segment M0 aligned with each of the adjacent instances of cell CD and CE, in addition to the locations corresponding to tracks T1-T3. A first case of the adjacent instances of cells CD and CJ corresponds to the embodiment depicted in FIG. 5 in which the three locations aligned with cell CD and the five locations aligned with cell CJ conform to a single frontside metal pitch.

In a second case of the adjacent instances of cells CD and CJ, a total of four locations corresponding to instances of frontside metal region/segment M0 are aligned with cell CD and conform to a first pitch P3 and a total of five locations corresponding to instances of frontside metal region/segment M0 are aligned with cell CJ and conform to a second pitch P4 greater than first pitch P3.

Compared to frontside power rail based embodiments as illustrated in FIGS. 4A and 4B, the backside power rail based embodiments depicted in FIGS. 5 and 6 allow the relatively wider instances of active region/area AA in cell CJ and thereby correspond to increased current driving capability. In the first embodiment depicted in FIGS. 5 and 6, the total of five locations corresponding to instances of frontside metal region/segment M0 aligned with cell CJ enable increased routing flexibility, and in the second embodiment depicted in FIG. 6, the total of four locations corresponding to instances of frontside metal region/segment M0 aligned with cell CJ and conforming to pitch P4 enable the use of relatively wider instances of frontside metal region/segment M0, thereby reducing parasitic resistance values.

FIG. 7 is a flowchart of method 700 of manufacturing an IC device, in accordance with some embodiments. Method 700 is operable to form some or all of one or more embodiments of IC device 100 discussed above with respect to FIGS. 1-6.

In some embodiments, performing some or all of the operations of method 700 is part of building a plurality of IC devices, e.g., transistors, logic gates, memory cells, interconnect structures, and/or other suitable devices, by performing a plurality of manufacturing operations, e.g., one or more of a lithography, diffusion, deposition, etching, planarizing, or other operation suitable for building the plurality of IC devices in a semiconductor wafer.

In some embodiments, the operations of method 700 are performed in the order depicted in FIG. 7. In some embodiments, the operations of method 700 are performed in an order other than the order depicted in FIG. 7. In some embodiments, one or more additional operations are performed before, during, and/or after the operations of method 700. In some embodiments, performing some or all of the operations of method 700 includes performing one or more operations as discussed below with respect to IC manufacturing system 1000 and FIG. 10.

At operation 702, in some embodiments, a semiconductor substrate is received. In some embodiments, receiving the semiconductor substrate includes receiving a silicon substrate or silicon-on-insulator (SOI) substrate. In some embodiments, receiving the semiconductor substrate includes receiving substrate SUB discussed above with respect to FIGS. 1-6.

At operation 704, a plurality of cells is constructed in the semiconductor substrate, a first cell active area having a first width and a first distance to a center line, and an active area in an adjacent second cell having a second width greater than the first width and a second distance to the center line less than the first distance. In some embodiments, constructing the plurality of cells includes constructing some or all of cells C1-C12 and/or cells CA-CJ including corresponding instances of active area AA discussed above with respect to FIGS. 1-6.

In some embodiments, constructing the plurality of cells includes forming the active areas by performing one or more deposition and/or implantation processes in areas of the semiconductor substrate.

In some embodiments, constructing the plurality of cells includes forming MD segments and via structures, e.g., instances of MD segment MD and via structure VD discussed above with respect to FIGS. 1-6, on the active areas by performing a plurality of manufacturing operations including depositing and patterning one or more photoresist layers, performing one or more etching processes, and performing one or more deposition processes.

In some embodiments, constructing the plurality of cells includes constructing a plurality of gate structures and isolation structures, e.g., instances of gate structure G and isolation structure IS discussed above with respect to FIGS. 1-6, by performing a plurality of manufacturing operations, e.g., one or more of a lithography, diffusion, deposition, etching, planarizing, or other operation suitable for constructing instances of gate structure G and isolation structure IS as discussed above with respect to FIGS. 1-6.

At operation 706, in some embodiments, first through third frontside or backside power rails are formed aligned to the center line and tracks corresponding to borders of each of the first and second cells. In some embodiments, forming the first through third frontside or backside power rails includes forming frontside or backside power rails aligned with tracks T1-T4 as discussed above with respect to FIGS. 1-6.

In some embodiments, forming the first through third frontside or backside power rails includes forming frontside power rails PR1-PR3 or backside power rails PR4-PR6 as discussed above with respect to FIGS. 1-6.

In some embodiments, forming the first through third frontside or backside power rails includes forming frontside power rails as part of performing operation 708 discussed below. In some embodiments, forming the first through third frontside or backside power rails includes forming backside power rails after performing operation 708 discussed below.

In some embodiments, forming metal segments, e.g., frontside or backside power rails, includes forming the one or more metal segments and/or via structures by performing a plurality of manufacturing operations including depositing and patterning one or more photoresist layers, performing one or more etching processes, and performing one or more deposition processes whereby one or more conductive materials are configured to form a continuous, low resistance structure.

At operation 708, in some embodiments, a plurality of metal segments is formed in the lowermost frontside metal layer electrically connected to the first and second cells. In some embodiments, forming the plurality of metal segments in the lowermost frontside metal layer includes forming instances of metal segment M0 as discussed above with respect to FIGS. 1-6.

In some embodiments, forming the plurality of metal segments in the lowermost frontside metal layer includes forming frontside power rails, e.g., frontside power rails PR1-PR3 discussed above with respect to FIGS. 1-6.

In some embodiments, forming the plurality of metal segments in the lowermost frontside metal layer includes constructing electrical connections by forming metal segments and/or via structures (e.g., VD) in one or more frontside metal layers above the lowermost frontside metal layer and/or forming metal segments and/or via structures in one or more backside metal layers.

By performing some or all of the operations of method 700, an IC device is manufactured in which rows of cells include a first cell active area having a first width and a first distance to the center line, and an active area in an adjacent second cell having a second width greater than the first width and a second distance to the center line less than the first distance, thereby enabling the realization of the benefits discussed above with respect to the embodiments of IC device 100.

FIGS. 8A-8C are flowcharts of method 800 of manufacturing an IC based on an IC layout diagram, in accordance with some embodiments. In some embodiments, generating the IC layout diagram includes generating the IC layout diagram corresponding to an IC device manufactured based on the generated IC layout diagram.

In some embodiments, some or all of method 800 is executed by at least one processor of one or more computers, e.g., one or more instances of a processor 902 of EDA system 900, discussed below with respect to FIG. 9.

Some or all of the operations of method 800 are capable of being performed as part of a design procedure performed in a design house, e.g., a design house 1020 discussed below with respect to FIG. 10.

In some embodiments, the operations of method 800 are performed in the order depicted in FIG. 8A. In some embodiments, the operations of method 800 are performed simultaneously and/or in an order other than the order depicted in FIG. 8. In some embodiments, one or more operations are performed before, between, during, and/or after performing one or more operations of method 800. In some embodiments, one or more of the operations of method 800 are repeated.

At operation 802, a plurality of cells is arranged in an IC layout diagram, a first cell active region having a first width and a first distance to a center power rail track, and an active region in an adjacent second cell having a second width greater than the first width and a second distance to the center power rail track less than the first distance.

In some embodiments, arranging the plurality of cells includes arranging some or all of cells C1-C12 and/or cells CA-CJ including corresponding instances of active region AA relative to one or more of tracks T1-T4 in one or more embodiments of IC layout diagram 100 as discussed above with respect to FIGS. 1-6.

In some embodiments, arranging the plurality of cells includes arranging instances of gate regions G and isolation regions IS as discussed above with respect to FIGS. 1-6.

In some embodiments, arranging the plurality of cells includes determining that at least one instance of an active region of a cell is a timing critical path of the cell. In some embodiments, an active region is determined to be a timing critical path if the active area includes one or more transistors having a significant effect on timing-related cell performance. The significance of an effect on timing-related cell performance is based on one or more predetermined criteria, e.g., rise time, fall time, switching speed, circuit bandwidth, or the like.

In some embodiments, arranging the plurality of cells includes performing operation 802-1 in accordance with the flowchart of FIG. 8B. In the embodiment depicted in FIG. 8B, a design flow includes some or all of a placement operation, a clock tree synthesis, a routing operation, a setup timing analysis, and an ECO operation. Arranging the plurality of cells is performed as part of the ECO operation in which, after identifying one or more active regions in corresponding cells as critical paths, the one or more cells previously placed in the IC layout diagram in the placement operation are replaced, e.g., by retrieving one or more corresponding cells from a storage device, e.g., a cell library 906 discussed below with respect to FIG. 9.

In some embodiments, arranging the plurality of cells includes performing operation 802-2 in accordance with the flowchart of FIG. 8C. In the embodiment depicted in FIG. 8C, a design flow includes some or all of a synthesis (gate-level netlist generation) operation, a floorplan layout operation, a power-plan layout operation, a placement operation, a clock tree synthesis, and a routing operation. Arranging the plurality of cells is performed as part of the placement operation in which, after identifying one or more active regions in corresponding cells as critical paths, the one or more cells are placed in the IC layout diagram in the placement operation, e.g., by retrieving one or more corresponding cells from the storage device, e.g., cell library 906 discussed below with respect to FIG. 9.

Compared to other approaches, each of operations 802-1 and 802-2 enhances layout efficiency. Operation 802-1 avoids a potential need for one or more layout and/or routing revisions after the placement operation, and operation 802-2 enables enhancements potentially greater than those provided by operation 802-1.

In some embodiments, arranging the plurality of cells includes overlapping the first cell active region with an MD region and overlapping the MD region and a center power rail with a via region, e.g., overlapping active region AA of cell CD with MD region MD and overlapping MD region MD and power rail PR2 with via region VD as discussed above with respect to FIGS. 4A and 4B.

In some embodiments, arranging the plurality of cells in the IC layout diagram includes overlapping the first active region of the first cell of the first row of cells with the center power rail track, e.g., overlapping the first instance of active region AA in cell CJ with track T2 as discussed above with respect to FIGS. 5 and 6.

At operation 804, a plurality of power rails is aligned with a plurality of power rails tracks including the center power rail track. In some embodiments, aligning the plurality of power rails with the plurality of power rail tracks includes aligning frontside power rails PR1-PR3 or backside power rails PR4-PR6 with tracks T1-T4 including track T2 as discussed above with respect to FIGS. 1-6.

At operation 806, in some embodiments, each of the first and second cells is overlapped with a plurality of frontside metal regions. In some embodiments, overlapping the first and second cells with the plurality of frontside metal regions includes overlapping one or more of cells C1-C12 and/or cells CA-CJ with metal regions M0 corresponding to one or more of pitches P1-P4 as discussed above with respect to FIGS. 1-6.

In some embodiments, overlapping the first and second cells with the plurality of frontside metal segments includes forming electrical connections by overlapping the plurality of frontside metal regions in a first frontside metal layer with one or more via regions and/or metal regions in one or more additional frontside metal layers and/or arranging metal and/or via regions in one or more backside metal layers.

At operation 808, in some embodiments, the IC layout diagram is stored in a storage device. In some embodiments, storing the IC layout diagram in the storage device includes storing one or more embodiments of IC layout diagram 100, discussed above with respect to FIGS. 1-6, in the storage device.

In some embodiments, storing the IC layout diagram in the storage device includes storing the IC layout diagram in a non-volatile, computer-readable memory or a database, and/or includes storing the IC layout diagram over a network. In some embodiments, storing the IC layout diagram in the storage device includes storing the IC layout diagram in IC layout diagrams 907 and/or over network 914 of IC layout diagram generation system 900, discussed below with respect to FIG. 9.

At operation 812, in some embodiments, one or more manufacturing operations, one or more lithographic exposures, are performed based on the IC layout diagram. Non-limiting examples of performing one or more manufacturing operations, e.g., one or more lithographic exposures, based on the IC layout diagram are discussed below with respect to FIG. 10.

By executing some or all of the operations of method 800, an IC device is manufactured based on an IC layout diagram in which a first cell active region has a first width and a first distance to a center power rail track, and an active region in an adjacent second cell has a second width greater than the first width and a second distance to the center power rail track less than the first distance, thereby being capable of realizing the benefits discussed above with respect to the embodiments of IC layout diagram/device 100.

FIG. 9 is a block diagram of an electronic design automation (EDA) system 900 in accordance with some embodiments. Methods described herein of designing IC layout diagrams, in accordance with one or more embodiments, are implementable using EDA system 900, in accordance with some embodiments.

In some embodiments, EDA system 900 is one or more instances of a general purpose computing device, each instance including a hardware processor 902 and a non-transitory, computer-readable storage medium 904. Storage medium 904, amongst other things, is encoded with, i.e., stores, computer program code 905, also referred to as instructions 905 in some embodiments, and some or all of cell library 906 and/or IC layout diagrams 907. Execution of instructions 905 by hardware processor 902 represents (at least in part) an EDA system which implements a portion or all of the methods described herein in accordance with one or more embodiments (hereinafter, the noted processes and/or methods).

Processor 902 is electrically coupled to computer-readable storage medium 904 via a bus 908. Processor 902 is also electrically coupled to an I/O interface 910 by bus 908. A network interface 912 is also electrically connected to processor 902 via bus 908. Network interface 912 is connected to a network 914, so that processor 902 and computer-readable storage medium 904 are capable of connecting to external elements via network 914. Processor 902 is configured to execute computer program code 905 encoded in computer-readable storage medium 904 in order to cause system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, computer-readable storage medium 904 is an electronic, magnetic, optical, electromagnetic, infrared, and/or a semiconductor system (or apparatus or device). For example, computer-readable storage medium 904 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 904 includes a compact disk-read only memory (CD-ROM), a compact disk-read/write (CD-R/W), and/or a digital video disc (DVD).

In one or more embodiments, storage medium 904 stores computer program code 905 configured to cause system 900 (where such execution represents (at least in part) the EDA system) to be usable for performing a portion or all of the noted processes and/or methods. In one or more embodiments, storage medium 904 also stores information which facilitates performing a portion or all of the noted processes and/or methods. In one or more embodiments, storage medium 904 stores cell library 906 including cells as disclosed herein, e.g., cells C1-C12 and/or CA-CI discussed above and/or IC layout diagrams 907 including IC layout diagrams as disclosed herein, e.g., one or more embodiments of IC layout diagram 100 discussed above.

EDA system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

EDA system 900 also includes network interface 912 coupled to processor 902. Network interface 912 allows system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 900.

System 900 is configured to receive information through I/O interface 910. The information received through I/O interface 910 includes one or more of instructions, data, design rules, libraries of standard cells, and/or other parameters for processing by processor 902. The information is transferred to processor 902 via bus 908. EDA system 900 is configured to receive information related to a user interface (UI) through I/O interface 910. The information is stored in computer-readable medium 904 as UI 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 900.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 10 is a block diagram of an integrated circuit (IC) manufacturing system 1000, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1000.

In FIG. 10, IC manufacturing system 1000 includes entities, such as a design house 1020, a mask house 1030, and an IC manufacturer/fabricator (fab) 1050, that interact with one another in the design, development, and manufacturing cycles and/or services related to manufacturing an IC device 1060. The entities in system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022, e.g., including one or more embodiments of IC layout diagram 100 discussed above with respect to FIGS. 1-6. IC design layout diagram 1022 includes various geometrical patterns designed for an IC device 1060. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place and route. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. Mask house 1030 uses IC design layout diagram 1022 to manufacture one or more masks 1045 to be used for fabricating the various layers of IC device 1060 according to IC design layout diagram 1022. Mask house 1030 performs mask data preparation 1032, where IC design layout diagram 1022 is translated into a representative data file (RDF). Mask data preparation 1032 provides the RDF to mask fabrication 1044. Mask fabrication 1044 includes a mask writer. A mask writer converts the RDF to an image on a substrate, such as a mask (reticle) 1045 or a semiconductor wafer 1053. The design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for photolithographic implementation effects during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

After mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 is an IC fabrication business that includes one or more manufacturing facilities for the fabrication of a variety of different IC products. In some embodiments, IC Fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 includes fabrication tools 1052 configured to execute various manufacturing operations on semiconductor wafer 1053 such that IC device 1060 is fabricated in accordance with the mask(s), e.g., mask 1045. In various embodiments, fabrication tools 1052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

In some embodiments, an IC device includes first through third power rails extending in a first direction, wherein the second power rail is aligned with a center line midway between the first and third power rails, and a plurality of cells including first and second rows of cells adjacent to each other and extending from the first power rail to the third power rail in a second direction perpendicular to the first direction, wherein each cell of the plurality of cells includes a total of two active areas extending in the first direction from a first isolation structure to a second isolation structure and having corresponding widths in the second direction, a first active area of the two active areas of each cell is between the second active area of the two active areas and the center line, first and second cells of the first row of cells are aligned with respective third and fourth cells of the second row of cells in the second direction, the first active area of the first cell has a first width and a first distance from the center line, the first active area of each of the second cell and the fourth cell has a second width greater than the first width and a second distance from the center line less than the first distance from the center line, and the first active area of the third cell has a third width greater than the second width and a third distance from the center line less than the second distance from the center line. In some embodiments, the first through third power rails include frontside power rails. In some embodiments, the IC device includes a first MD segment extending in the second direction and overlying and electrically connected to the first active area of the first cell of the first row of cells, a first via extending between and electrically connected to the first MD segment and the second power rail and having a fourth width in the second direction, a second MD segment extending in the second direction and overlying and electrically connected to the first active area of the second cell of the first row of cells, and a second via extending between and electrically connected to the second MD segment and the second power rail and having a fifth width in the second direction greater than the fourth width, wherein the second MD segment extends further under the second power rail than the first MD segment. In some embodiments, the IC device includes a first MD segment extending in the second direction and overlying and electrically connected to the first active area of the first cell of the first row of cells, a first via extending between and electrically connected to the first MD segment and the second power rail at a first location and having a fourth width in the second direction, a second MD segment extending in the second direction and overlying and electrically connected to the first active area of the second cell of the first row of cells, and a second via extending between and electrically connected to the second MD segment and the second power rail at a second location and having the fourth width in the second direction, wherein the second power rail has a fifth width in the second direction at the first location greater than a sixth width in the second direction at the second location. In some embodiments, the first through third power rails include backside power rails. In some embodiments, the IC device includes a plurality of frontside metal lines overlying the first cell of the first row of cells and the third cell of the second row of cells, extending in the first direction, and spaced in the second direction according to a single pitch. In some embodiments, the IC device includes a first plurality of frontside metal lines overlying the first cell of the first row of cells, extending in the first direction, and spaced in the second direction according to a first pitch, and a second plurality of frontside metal lines overlying the third cell of the second row of cells, extending in the first direction, and spaced in the second direction according to a second pitch greater than the first pitch. In some embodiments, the center line is a first center line, the IC device includes a fourth power rail extending in the first direction, wherein the third power rail is aligned with a second center line midway between the second and fourth power rails, the plurality of cells includes a third row of cells extending from the third power rail to the fourth power rail in the second direction, the first active area of the two active areas of each cell of the third row of cells is between the second active area of the two active areas and the second center line, a fifth cell of the third row of cells is aligned with the third cell of the second row of cells in the second direction, the second active area of the third cell has the third width and the third distance from the second center line, and the first active area of the fifth cell has the first width and the first distance from the second center line.

In some embodiments, method of manufacturing an IC device includes arranging, in an IC layout diagram, a plurality of cells including first and second rows of cells adjacent to each other and extending in a first direction from a first power rail track extending in a second direction perpendicular to the first direction to a second power rail track extending in the second direction, wherein a third power rail track extends midway between the first and second power rail tracks, each cell of the plurality of cells includes a total of two active regions extending in the second direction from a first border to a second border and having corresponding widths in the first direction, a first active region of the two active regions of each cell is between the second active region of the two active regions and the third power rail track, first and second cells of the first row of cells are aligned with respective third and fourth cells of the second row of cells in the first direction, the first active region of the first cell has a first width and a first distance from the third power rail track, the first active region of each of the second cell and the fourth cell has a second width greater than the first width and a second distance from the third power rail track less than the first distance from the third power rail track, and the first active region of the third cell has a third width greater than the second width and a third distance from the third power rail track less than the second distance from the third power rail track, and storing the IC layout diagram including the plurality of cells arranged relative to the first through third power rail tracks in a storage device. In some embodiments, arranging the plurality of cells in the IC layout diagram includes placing the plurality of cells in the IC layout diagram, performing a routing operation to the plurality of cells, and after the performing the routing operation, based on the first active region of the third cell of the plurality of cells being identified as a critical path, causing the first active region of the third cell of the plurality of cells to have the third width greater than the second width and the third distance from the third power rail track less than the second distance from the third power rail track by replacing or modifying the third cell of the plurality of cells. In some embodiments, arranging the plurality of cells in the IC layout diagram includes, based on the first active region of the third cell of the plurality of cells being identified as a critical path, placing, in the IC layout diagram, the plurality of cells comprising the first active region of the third cell having the third width greater than the second width and the third distance from the third power rail track less than the second distance from the third power rail track, and after the placing the plurality of cells in the IC layout diagram, performing a routing operation to the plurality of cells. In some embodiments, the method includes aligning first through third frontside power rails with the respective first through third power rail tracks, wherein the storing the IC layout diagram in the storage device includes storing the IC layout diagram including the first through third frontside power rails aligned with the first through third power rail tracks. In some embodiments, arranging the plurality of cells includes overlapping each of the first active region of the first cell of the first row of cells and the second frontside power rail with a first MD region, overlapping each of the second frontside power rail and the first MD region with a first via region having a fourth width in the first direction, overlapping each of the first active region of the second cell of the first row of cells and the second front-side power rail with a second MD region, overlapping each of the second frontside power rail and the second MD region with a second via region having a fifth width in the first direction greater than the fourth width, wherein the second MD region overlaps a larger portion of the second power rail than the first MD region, and storing the IC layout diagram in the storage device includes storing the IC layout diagram further comprising the first and second MD regions and the first and second via regions. In some embodiments, arranging the plurality of cells includes overlapping each of the first active region of the first cell of the first row of cells and the second frontside power rail with a first MD region, overlapping, at a first location, each of the second front-side power rail and the first MD region with a first via region having a fourth width in the first direction, overlapping each of the first active region of the second cell of the first row of cells and the second frontside power rail with a second MD region, overlapping, at a second location, each of the second frontside power rail and the second MD region with a second via region having the fourth width in the first direction, wherein the second power rail has a fifth width in the first direction at the first location greater than a sixth width in the first direction at the second location, and storing the IC layout diagram in the storage device includes storing the IC layout diagram including the first and second MD regions and the first and second via regions. In some embodiments, the method includes aligning first through third backside power rails with the respective first through third power rail tracks, wherein the storing the IC layout diagram in the storage device includes storing the IC layout diagram including the first through third backside power rails aligned with the first through third power rail tracks. In some embodiments, arranging the plurality of cells in the IC layout diagram includes overlapping the first active region of the first cell of the first row of cells with the second power rail track.

In some embodiments, a method of manufacturing an IC device includes constructing, in a semiconductor substrate, a plurality of cells including first and second rows of cells adjacent to each other and extending in a first direction from a first power rail track extending in a second direction perpendicular to the first direction to a second power rail track extending in the second direction, wherein a third power rail track extends midway between the first and second power rail tracks, each cell of the plurality of cells includes a total of two active areas extending in the second direction from a first isolation structure to a second isolation structure and having corresponding widths in the first direction, a first active area of the two active areas of each cell is between the second active area of the two active areas and the third power rail track, first and second cells of the first row of cells are aligned with respective third and fourth cells of the second row of cells in the first direction, the first active area of the first cell has a first width and a first distance from the third power rail track, the first active area of each of the second cell and the fourth cell has a second width greater than the first width and a second distance from the third power rail track less than the first distance from the third power rail track, and the first active area of the third cell has a third width greater than the second width and a third distance from the third power rail track less than the second distance from the third power rail track; and forming first through third power rails aligned with the respective first through third power rail tracks. In some embodiments, forming the first through third power rails includes forming first through third frontside power rails aligned with the respective first through third power rail tracks. In some embodiments, constructing the plurality of cells includes forming a first MD segment on the first active area of the first cell of the first row of cells and extending in the first direction to an endpoint a fourth distance from the second power rail track; and forming a second MD segment on the first active area of the second cell of the first row of cells and extending in the first direction to an endpoint a fifth distance from the third power rail track less than the fourth distance from the second power rail track. In some embodiments, forming the first through third power rails includes forming first through third backside power rails aligned with the respective first through third power rail tracks.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising:
first through third power rails extending in a first direction, wherein the second power rail is aligned with a center line midway between the first and third power rails; and
a plurality of cells comprising first and second rows of cells adjacent to each other and extending from the first power rail to the third power rail in a second direction perpendicular to the first direction,
wherein
each cell of the plurality of cells comprises a total of two active areas extending in the first direction from a first isolation structure to a second isolation structure and having corresponding widths in the second direction,
a first active area of the two active areas of each cell is between the second active area of the two active areas and the center line,
first and second cells of the first row of cells are aligned with respective third and fourth cells of the second row of cells in the second direction,
the first active area of the first cell has a first width and a first distance from the center line,
the first active area of each of the second cell and the fourth cell has a second width greater than the first width and a second distance from the center line less than the first distance from the center line, and
the first active area of the third cell has a third width greater than the second width and a third distance from the center line less than the second distance from the center line.

2. The IC device of claim 1, wherein
the first through third power rails comprise frontside power rails.

3. The IC device of claim 2, further comprising:
a first metal-diffusion (MD) segment extending in the second direction and overlying and electrically connected to the first active area of the first cell of the first row of cells;
a first via extending between and electrically connected to the first MD segment and the second power rail and having a fourth width in the second direction;
a second MD segment extending in the second direction and overlying and electrically connected to the first active area of the second cell of the first row of cells; and
a second via extending between and electrically connected to the second MD segment and the second power rail and having a fifth width in the second direction greater than the fourth width,
wherein the second MD segment extends further under the second power rail than the first MD segment.

4. The IC device of claim 2, further comprising:
a first metal-diffusion (MD) segment extending in the second direction and overlying and electrically connected to the first active area of the first cell of the first row of cells;
a first via extending between and electrically connected to the first MD segment and the second power rail at a first location and having a fourth width in the second direction;
a second MD segment extending in the second direction and overlying and electrically connected to the first active area of the second cell of the first row of cells; and
a second via extending between and electrically connected to the second MD segment and the second power rail at a second location and having the fourth width in the second direction,
wherein the second power rail has a fifth width in the second direction at the first location greater than a sixth width in the second direction at the second location.

5. The IC device of claim 1, wherein the first through third power rails comprise backside power rails.

6. The IC device of claim 5, further comprising:
a plurality of frontside metal lines overlying the first cell of the first row of cells and the third cell of the second row of cells, extending in the first direction, and spaced in the second direction according to a single pitch.

7. The IC device of claim 5, further comprising:
a first plurality of frontside metal lines overlying the first cell of the first row of cells, extending in the first direction, and spaced in the second direction according to a first pitch; and
a second plurality of frontside metal lines overlying the third cell of the second row of cells, extending in the first direction, and spaced in the second direction according to a second pitch greater than the first pitch.

8. The IC device of claim 1, wherein
the center line is a first center line,
the IC device further comprises a fourth power rail extending in the first direction, wherein the third power rail is aligned with a second center line midway between the second and fourth power rails,
the plurality of cells further comprises a third row of cells extending from the third power rail to the fourth power rail in the second direction,
the first active area of the two active areas of each cell of the third row of cells is between the second active area of the two active areas and the second center line,
a fifth cell of the third row of cells is aligned with the third cell of the second row of cells in the second direction,
the second active area of the third cell has the third width and the third distance from the second center line, and
the first active area of the fifth cell has the first width and the first distance from the second center line.

9. A method of manufacturing an integrated circuit (IC) device, the method comprising:
arranging, in an IC layout diagram, a plurality of cells comprising first and second rows of cells adjacent to each other and extending in a first direction from a first power rail track extending in a second direction perpendicular to the first direction to a second power rail track extending in the second direction,
wherein
a third power rail track extends midway between the first and second power rail tracks,
each cell of the plurality of cells comprises a total of two active regions extending in the second direction from a first border to a second border and having corresponding widths in the first direction,
a first active region of the two active regions of each cell is between the second active region of the two active regions and the third power rail track,
first and second cells of the first row of cells are aligned with respective third and fourth cells of the second row of cells in the first direction,
the first active region of the first cell has a first width and a first distance from the third power rail track,
the first active region of each of the second cell and the fourth cell has a second width greater than the first width and a second distance from the third power rail track less than the first distance from the third power rail track, and
the first active region of the third cell has a third width greater than the second width and a third distance from the third power rail track less than the second distance from the third power rail track; and
storing the IC layout diagram comprising the plurality of cells arranged relative to the first through third power rail tracks in a storage device.

10. The method of claim 9, wherein the arranging the plurality of cells in the IC layout diagram comprises:
placing the plurality of cells in the IC layout diagram;
performing a routing operation to the plurality of cells; and
after the performing the routing operation, based on the first active region of the third cell of the plurality of cells being identified as a critical path, causing the first active region of the third cell of the plurality of cells to have the third width greater than the second width and the third distance from the third power rail track less than the second distance from the third power rail track by replacing or modifying the third cell of the plurality of cells.

11. The method of claim 9, wherein the arranging the plurality of cells in the IC layout diagram comprises:
based on the first active region of the third cell of the plurality of cells being identified as a critical path, placing, in the IC layout diagram, the plurality of cells comprising the first active region of the third cell having the third width greater than the second width and the third distance from the third power rail track less than the second distance from the third power rail track; and
after the placing the plurality of cells in the IC layout diagram, performing a routing operation to the plurality of cells.

12. The method of claim 9, further comprising:
aligning first through third frontside power rails with the respective first through third power rail tracks,
wherein the storing the IC layout diagram in the storage device comprises storing the IC layout diagram further comprising the first through third frontside power rails aligned with the first through third power rail tracks.

13. The method of claim 12, wherein the arranging the plurality of cells comprises:
overlapping each of the first active region of the first cell of the first row of cells and the second frontside power rail with a first metal-diffusion (MD) region;
overlapping each of the second frontside power rail and the first MD region with a first via region having a fourth width in the first direction;
overlapping each of the first active region of the second cell of the first row of cells and the second front-side power rail with a second MD region;
overlapping each of the second frontside power rail and the second MD region with a second via region having a fifth width in the first direction greater than the fourth width,
wherein
the second MD region overlaps a larger portion of the second power rail than the first MD region, and
the storing the IC layout diagram in the storage device comprises storing the IC layout diagram further comprising the first and second MD regions and the first and second via regions.

14. The method of claim 12, wherein the arranging the plurality of cells comprises:
overlapping each of the first active region of the first cell of the first row of cells and the second frontside power rail with a first metal-diffusion (MD) region;
overlapping, at a first location, each of the second front-side power rail and the first MD region with a first via region having a fourth width in the first direction;
overlapping each of the first active region of the second cell of the first row of cells and the second frontside power rail with a second MD region;
overlapping, at a second location, each of the second frontside power rail and the second MD region with a second via region having the fourth width in the first direction,
wherein
the second power rail has a fifth width in the first direction at the first location greater than a sixth width in the first direction at the second location, and
the storing the IC layout diagram in the storage device comprises storing the IC layout diagram further comprising the first and second MD regions and the first and second via regions.

15. The method of claim 9, further comprising:
aligning first through third backside power rails with the respective first through third power rail tracks,
wherein the storing the IC layout diagram in the storage device comprises storing the IC layout diagram further comprising the first through third backside power rails aligned with the first through third power rail tracks.

16. The method of claim 15, wherein
the arranging the plurality of cells in the IC layout diagram comprises overlapping the first active region of the first cell of the first row of cells with the second power rail track.

17. A method of manufacturing an integrated circuit (IC) device, the method comprising:
constructing, in a semiconductor substrate, a plurality of cells comprising first and second rows of cells adjacent to each other and extending in a first direction from a first power rail track extending in a second direction perpendicular to the first direction to a second power rail track extending in the second direction,
wherein
a third power rail track extends midway between the first and second power rail tracks,
each cell of the plurality of cells comprises a total of two active areas extending in the second direction from a first isolation structure to a second isolation structure and having corresponding widths in the first direction,
a first active area of the two active areas of each cell is between the second active area of the two active areas and the third power rail track,
first and second cells of the first row of cells are aligned with respective third and fourth cells of the second row of cells in the first direction,
the first active area of the first cell has a first width and a first distance from the third power rail track,
the first active area of each of the second cell and the fourth cell has a second width greater than the first width and a second distance from the third power rail track less than the first distance from the third power rail track, and
the first active area of the third cell has a third width greater than the second width and a third distance from the third power rail track less than the second distance from the third power rail track; and
forming first through third power rails aligned with the respective first through third power rail tracks.

18. The method of claim 17, wherein
the forming the first through third power rails comprises forming first through third frontside power rails aligned with the respective first through third power rail tracks.

19. The method of claim 18, wherein the constructing the plurality of cells comprises:
forming a first metal-diffusion (MD) segment on the first active area of the first cell of the first row of cells and extending in the first direction to an endpoint a fourth distance from the second power rail track; and
forming a second MD segment on the first active area of the second cell of the first row of cells and extending in the first direction to an endpoint a fifth distance from the third power rail track less than the fourth distance from the second power rail track.

20. The method of claim 17, wherein
the forming the first through third power rails comprises forming first through third backside power rails aligned with the respective first through third power rail tracks.
